(19) United States
(12) Patent Application Publication
(10) Pub. No.: US 2026/0255783 A1
(43) Pub. Date: Aug. 27, 2026

(54) QUANTUM DOT ELECTROLUMINESCENT DEVICE AND METHOD FOR MANUFACTURING SAME, AND DISPLAY DEVICE

(71) Applicants: Beijing BOE Technology Development Co., Ltd., Beijing (CN); BOE Technology Group Co., Ltd., Beijing (CN)

(72) Inventor: Maocheng JIANG, Beijing (CN)

(21) Appl. No.: 18/994,110

(22) PCT Filed: Apr. 17, 2024
(86) PCT No.: PCT/CN2024/088329

§ 371 Date: Jan. 14, 2025

(30) Foreign Application Priority Data
May 26, 2023 (CN) 202310614002.9

(51) Int. Cl. H10K 50/15; H10K 50/115; H10K 71/12; H10K 85/10; H10K 85/20

(52) U.S. Cl. CPC H10K 50/15; H10K 50/115; H10K 71/12; H10K 85/113; H10K 85/221

(57) ABSTRACT

Provided is a quantum dot electroluminescent device. The quantum dot electroluminescent device includes an anode layer, a functional layer, and a cathode layer that are stacked; wherein the functional layer includes a quantum dot light-emitting layer, and a hole transport layer and an electron transport layer that are disposed on two sides of the quantum dot light-emitting layer, wherein the hole transport layer includes a hole transport material and carbon nanotubes, the hole transport material being bonded to the carbon nanotubes.

### CROSS-REFERENCE TO RELATED APPLICATION

This application is a U.S. national stage of international application No. PCT/CN 2024/088329, filed on Apr. 17, 2024, which claims priority to Chinese Patent Application No. 202310614002.9, filed on May 26, 2023 and entitled “QUANTUM DOT ELECTROLUMINESCENT DEVICE AND MANUFACTURING METHOD THEREFOR, AND DISPLAY DEVICE” the disclosures of which are herein incorporated by references in their entireties.

### TECHNICAL FIELD

The present disclosure relates to the technical field of display, and in particular, relates to a quantum dot electroluminescent device and a method for manufacturing the same, and a display device.

### BACKGROUND

Quantum dot light emitting diodes (QLEDs) are electroluminescent devices. A QLED includes a quantum dot light-emitting layer, a hole transport layer, and an electron transport layer.

### SUMMARY

In view of this, a quantum dot electroluminescent device and a method for manufacturing the same, and a display device are provided in the present disclosure.

Specifically, the following technical solutions are provided.

In some embodiments of the present disclosure, a quantum dot electroluminescent device is provided. The quantum dot electroluminescent device includes: an anode layer, a functional layer, and a cathode layer that are stacked; wherein
the functional layer includes a quantum dot light-emitting layer, and a hole transport layer and an electron transport layer that are disposed on two sides of the quantum dot light-emitting layer,
wherein the hole transport layer includes a hole transport material and carbon nanotubes, the hole transport material being bonded to the carbon nanotubes.

In some embodiments, the hole transport material is an inorganic hole transport material,
wherein the inorganic hole transport material is filled in lumens of the carbon nanotubes.

In some embodiments, the carbon nanotubes are in contact with the anode layer.

In some embodiments, the inorganic hole transport material is selected from NiOx, MoOx, VOX, WOx, CrOx, CuO, MoS2, MoSe2, WS2, WSe2, CuS, or any combination thereof.

In some embodiments, the hole transport material being an organic hole transport material,
wherein at least part of the organic hole transport material is bonded to the carbon nanotubes through a noncovalent bonding force and is on outer surfaces of the carbon nanotubes.

In some embodiments, the carbon nanotubes and the organic hole transport material are both in contact with the anode layer.

In some embodiments, the organic hole transport material is selected from poly (9,9-dioctylfluorene-co-N-(4-butylphenyl) diphenylamine (TFB), polyvinyl carbazole (PVK), poly (N,N′-bis(4-butylphenyl)-N,N′-bis(phenyl)benzidine) (poly TPD), poly(9,9-dioctylfluorene-co-bis-N, N-phenyl-1,4-phenylenediamine) (PFB), 4,4′,4″-tri(carbazole-9-yl) triphenylamine (TCTA), 4,4′-di(9-carbazole)biphenyl (CBP), N,N′-diphenyl-N,N′-di(3-methylphenyl)-1,1′-biphenyl-4,4′-diamine (TPD), N,N′-diphenyl-N,N′-(1-naphthyl)-1,1′-biphenyl-4,4′-diamine (NPB), poly-3-hexylthiophene (P3HT), or any combination thereof.

In some embodiments, a mass of the carbon nanotubes is 1%-65% of a total mass of the hole transport material and the carbon nanotubes.

In some embodiments, the quantum dot electroluminescent device includes a red quantum dot light-emitting layer, a green quantum dot light-emitting layer, and a blue quantum dot light-emitting layer; wherein
the hole transport layer includes a first hole transport layer segment, a second hole transport layer segment, and a third hole transport layer segment, wherein the first hole transport layer segment corresponds to the red quantum dot light-emitting layer, the second hole transport layer segment corresponds to the green quantum dot light-emitting layer, and the third hole transport layer segment corresponds to the blue quantum dot light-emitting layer,
wherein mass proportions of the carbon nanotubes in the first hole transport layer segment, the second hole transport layer segment, and the third hole transport layer segment are gradually increased.

In some embodiments, the quantum dot light-emitting layer includes red quantum dots, and the mass of the carbon nanotubes is 1% to 25% of the total mass of the hole transport material and the carbon nanotubes; or
the quantum dot light-emitting layer includes green quantum dots, and the mass of the carbon nanotubes is 5% to 45% of the total mass of the hole transport material and the carbon nanotubes; or
the quantum dot light-emitting layer includes blue quantum dots, and the mass of the carbon nanotubes is 25% to 65% of the total mass of the hole transport material and the carbon nanotubes.

In some embodiments, the quantum dot electroluminescent device includes an upright bottom emitting device, an inverted bottom emitting device, an upright top emitting device, and an inverted top emitting device.

In some embodiments of the present disclosure, a method for manufacturing a quantum dot electroluminescent device is provided. The quantum dot electroluminescent device is any quantum dot electroluminescent device according to above embodiments;
the manufacturing method includes: forming an anode layer, a cathode layer, a quantum dot light-emitting layer, a hole transport layer, and an electron transport layer based on a structure of the quantum dot electroluminescent device;
wherein forming the hole transport layer includes: providing a hole transport material and carbon nanotubes;
acquiring a functional hole transport material by bonding the hole transport material to the carbon nanotubes; and
acquiring the hole transport layer based on the functional hole transport material.

In some embodiments, the hole transport material is an inorganic hole transport material, the inorganic hole transport material being filled in lumens of the carbon nanotubes; and
acquiring the functional hole transport material by bonding the hole transport material to the carbon nanotubes includes:
opening mouths of the carbon nanotubes;
acquiring a first intermediate of the functional hole transport material by causing a metal salt solution corresponding to the inorganic hole transport material to enter the lumens of the carbon nanotubes, wherein a surface tension of the metal salt solution is less than a predetermined threshold; and
acquiring the functional hole transport material by drying and annealing the first intermediate of the functional hole transport material.

In some embodiments, the surface tension of the metal salt solution ranges from 100 mN/m to 200 mN/m.

In some embodiments, the hole transport material is an inorganic hole transport material, the inorganic hole transport material being filled in lumens of the carbon nanotubes; and
acquiring the functional hole transport material by bonding the hole transport material to the carbon nanotubes includes:
opening mouths of the carbon nanotubes;
acquiring a second intermediate of the functional hole transport material by causing a dispersion of the inorganic hole transport material to enter the lumens of the carbon nanotubes; and
acquiring the functional hole transport material by post-processing the second intermediate of the functional hole transport material.

In some embodiments, the hole transport material is an organic hole transport material, the organic hole transport material is bonded to surfaces of the carbon nanotubes through a noncovalent bonding force; and
acquiring the functional hole transport material by bonding the hole transport material to the carbon nanotubes includes:
acquiring a dispersion of the organic hole transport material by uniformly dispersing the organic hole transport material in a solvent;
uniformly dispersing the carbon nanotubes in the dispersion of the organic hole transport material; and
acquiring the functional hole transport material by purifying the dispersion of the organic hole transport material mixed with the carbon nanotubes.

In some embodiments, purifying the dispersion of the organic hole transport material mixed with the carbon nanotubes includes:
a centrifugation process and a solvent extraction process in sequence.

In some embodiments of the present disclosure, a display device is provided. The display device includes: any quantum dot electroluminescent device according to above embodiments.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of an upright bottom emitting device according to some embodiments of the present disclosure;

FIG. 2 is a schematic structural diagram of an inverted bottom emitting device according to some embodiments of the present disclosure;

FIG. 3 is a schematic structural diagram of an upright top emitting device according to some embodiments of the present disclosure;

FIG. 4 is a schematic structural diagram of an inverted top emitting device according to some embodiments of the present disclosure;

FIG. 5 is a schematic structural diagram of a functional hole transport material including an organic hole transport material and a carbon nanotube and a flowchart of manufacturing the same according to some embodiments of the present disclosure; and

FIG. 6 is a schematic structural diagram of a functional hole transport material including an inorganic hole transport material and a carbon nanotube and a flowchart of manufacturing the same according to some embodiments of the present disclosure.

Reference numerals and denotations thereof:

101—transparent anode layer; 102—reflection anode later; 103—transparent cathode layer; 104—reflection cathode later; 200—hole transport layer; 300—quantum dot light-emitting layer; and 400—electron transport layer.

Specific embodiments of the present disclosure are illustrated based on above accompanying drawings, and detailed description are shown in the following description. The accompanying drawings and text description are not intended to limit the scope of the concept of the present disclosure in any manner, and are intended to describe the concept of the present disclosure for those skilled in the art based on the specific embodiments.

### DETAILED DESCRIPTION

The technical solutions according to the embodiments of the present disclosure are described clearly and completely hereinafter in combination with the accompanying drawings in the embodiments of the present disclosure. It is obvious that the described embodiments are merely part but not all of the embodiments of the present disclosure. All other embodiments derived by those skilled in the art without creative efforts based on the embodiments in the present disclosure are within the protection scope of the disclosure.

Illustrative embodiments are described in detail herein, and examples thereof are illustrated in the accompanying drawings. Unless otherwise defined, in the following description relates to accompanying drawings, the same numeral in different accompanying drawings represents the same or similar elements. The implementations described in the following illustrative embodiments do not represent all implementations consistent with the present disclosure, and are only examples of devices and methods that are consistent with aspects of the present disclosure as detailed in the accompanying drawings.

The orientation terms in the embodiments of the present disclosure, for example, “up,” “down,” and the like, are generally based on the relative relation of the orientations shown in FIG. 1, are used only to describe the structure and the relation between the structure s more clearly, and are not intended to describe the absolute orientation. When the product is disposed in different positions, the orientation changes, for example, the terms “up” and “down” are exchangeable.

Unless otherwise defined, all technical or scientific terms used in the present disclosure have the same meaning as the ordinary meaning understood by persons of ordinary skill in the art to which the present disclosure belongs. The technical terms in the embodiments of the present disclosure are described as following.

For clearer descriptions of the objectives and advantages of the present disclosure, embodiments of the present disclosure are described in detail hereinafter with reference to the accompanying drawings.

QLEDs are electroluminescent devices. A QLED includes a quantum dot light-emitting layer, a hole transport layer, and an electron transport layer. The hole transport layer and the electron transport layer are disposed on two sides of the quantum dot light-emitting layer. As such, under the effect of an external electric field, holes and electrons overcome interface barriers and enter a valence band and a conduction band of the quantum dot light-emitting layer respectively, and release photons when returning to a stable ground state from an excited state to emit light.

Currently, a ZnO electron transport layer is developed to greatly improve an electron injection efficiency. However, a hole mobility of the current hole transport layer is low, which causes poor compatibility of the current hole transport layer and the ZnO electron transport layer and a large barrier to be overcome for hole injection. Thus, the electrons are the majority in the device, and electron-hole injection is imbalance, and consequently the efficiency and service life of the device are affected.

In an aspect, some embodiments of the present disclosure provide a quantum dot electroluminescent device. The quantum dot electroluminescent device includes an anode layer, a functional layer, and a cathode layer that are stacked. The functional layer includes a quantum dot light-emitting layer, and a hole transport layer and an electron transport layer that are disposed on two sides of the quantum dot light-emitting layer.

The hole transport layer includes a hole transport material and carbon nanotubes. The hole transport material is bonded to the carbon nanotubes.

The hole transport material being bonded to the carbon nanotubes in the embodiments of the present disclosure means that the carbon nanotube has a binding force on the hole transport material, and thus the hole transport material and the carbon nanotube have a stable contact, such that the hole transport material and the carbon nanotube do not separate from each other and cooperate to form a functional hole transport material, which is different from a method for simply mixing the hole transport material and the carbon nanotube.

In the quantum dot electroluminescent device according to the embodiments of the present disclosure, the hole transport layer is improved, such that the manufacturing material includes the carbon nanotube and the hole transport material bonded to the carbon nanotube. As P electrons of carbon atoms in the carbon nanotube form a wide range of delocalized a bond, and the conjugation effect is significant, such that the carbon nanotube has excellent electrical conductivity. Based on the excellent electrical conductivity of the carbon nanotube, the hole mobility of the hole transport layer is improved by bonding the hole transport material to the highly conductive carbon nanotube, such that the electron-hole injection and transport in the quantum dot electroluminescence device are more balanced, and the efficiency and the service life of the quantum dot electroluminescence device are improved.

In some implementations, the hole transport material is an inorganic hole transport material. Referring to FIG. 5, the inorganic hole transport material is filled in lumens of the carbon nanotubes.

As a size of the cavity of the carbon nanotube is nanoscale, the hole transport material is stably bonded to the carbon nanotube by placing the inorganic hole transport material in the lumens of the carbon nanotube, and the quantum dot electroluminescent device with the high hole mobility is acquired.

For such quantum dot electroluminescent device, one or more types of the inorganic hole transport materials are filled in the carbon nanotube. For example, two, three, four, five, or more types of the inorganic hole transport materials are filled in the carbon nanotube. Thus, the hole mobility of the quantum dot electroluminescent device is adjusted to the desired level.

For such quantum dot electroluminescent device, in some embodiments, contact between the hole transport layer and the anode layer is achieved based on contact between the carbon nanotube and the anode layer, such that the hole mobility of the hole transport layer is improved.

All currently known inorganic hole transport materials are applicable to the present disclosure. For example, some common inorganic hole transport materials are doped or undoped transition metal oxides, doped or undoped metallic sulfur compounds, or a combination thereof.

Some exemplary transition metal oxides include, but are not limited to, NiOx, MoOx, VOx, WOx, CrOx, CuO, or any combination thereof. Some exemplary metallic sulfur compounds include, but are not limited to, MoS2, MoSe2, WS2, WSe2, CuS, or any combination thereof.

For NiOx, x ranges from 1 to 3, for example, 1, 2, 3, and the like. For MoOx, x ranges from 1 to 3, for example, 1, 2, 3, and the like. For NiOx, x ranges from 1 to 3, for example, 1, 2, 3, and the like. For MoOx, x ranges from 1 to 3, for example, 1, 2, 3, and the like. For VO, x ranges from 1 to 2.5, for example, 1, 1.5, 2, 2.5, and the like. For WOx, x ranges from 1 to 3, for example, 1, 2, 3, and the like. For CrOx, x ranges from 1 to 5, for example, 1, 2, 3, 4, 5, and the like.

In some embodiments, the inorganic hole transport material is oxide. For example, the inorganic hole transport material is a transition metal oxide.

The inorganic hole transport material in the oxide form enters the lumen of the carbon nanotube in the form of metal salt solution based on capillary action, such that the inorganic hole transport material in the oxide form is formed after drying and annealing treatment, which is conducive to simplifying the manufacturing process of the quantum dot electroluminescent device.

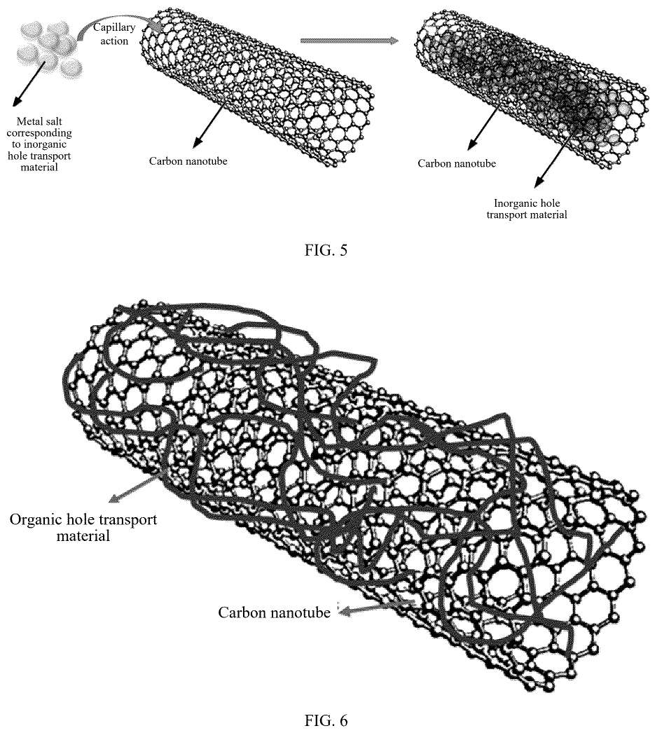

In some implementations, the hole transport material is an organic hole transport material. Referring to FIG. 6, at least part of the organic hole transport material is bonded to the carbon nanotubes through a noncovalent bonding force and is on outer surfaces of the carbon nanotubes.

The organic hole transport material includes at least one element connected to the carbon nanotubes through the noncovalent bond, and the formed functional hole transport material is a super-molecular nanohybrid.

Because the graphite form the sidewall lamellae structure of the carbon nanotube, carbon atoms are in a hybrid state, and the highly delocalized π electrons in the carbon nanotube interact with other substances (including electrons) based on the π-π bond effect. In the organic hole transport material, at least one element has electronegativity or polarity stronger than C and H elements. The element having stronger electronegativity or polarity is prior to interaction with π electrons in the carbon nanotube based on the noncovalent bonding force, for example, π-π conjugation, coordination effect, and van der Waals force, such that noncovalent bonding between the element and the π electrons is achieved, and a functional carbon nanotube is acquired. In this case, at least part of the organic hole transport material is bonded to the surface of the carbon nanotube to achieve stable recombination, such that a quantum dot electroluminescent device with the high hole mobility is acquired.

For such quantum dot electroluminescent device, in some embodiments, contact between the hole transport layer and the anode layer is achieved based on contact between the carbon nanotube and the anode layer and contact the organic hole transport material and the anode layer, such that the hole mobility of the hole transport layer is improved.

Some suitable organic hole transport materials are selected from TFB, PVK, poly-TPD, PFB, TCTA, CBP, TPD, NPB, P3HT, or any combination thereof.

Using P3HT as an example, S element therein has stronger electronegativity, and thus the P3HT is bonded to the surfaces of the carbon nanotubes through the S element based on the noncovalent bonding force.

In the embodiments of the present disclosure, the material composed of hole transport material and the carbon nanotubes is referred to as the functional hole transport material, and the hole mobility of the functional hole transport material is positively correlated with the amount of the carbon nanotubes. That is, the higher the amount of the carbon nanotubes, the higher the greater the hole mobility of the functional hole transport material.

As the quantum dots generally include red quantum dots, green quantum dots, and blue quantum dots, a mass of the carbon nanotubes is 1% to 65% of a total mass of the hole transport material and the carbon nanotubes to match the quantum dots.

The hole mobility of the functional hole transport material is adjusted based on the valence band of quantum dots in the quantum dot light-emitting layer. The higher the valence band of the quantum dots, the greater the desired hole mobility of the hole transport layer; the lower the valence band of the quantum dots, the less the desired hole mobility of the hole transport layer.

In some implementations, the quantum dot electroluminescent device includes a red quantum dot light-emitting layer, a green quantum dot light-emitting layer, and a blue quantum dot light-emitting layer. The hole transport layer includes a first hole transport layer segment, a second hole transport layer segment, and a third hole transport layer segment. The first hole transport layer segment corresponds to the red quantum dot light-emitting layer, the second hole transport layer segment corresponds to the green quantum dot light-emitting layer, and the third hole transport layer segment corresponds to the blue quantum dot light-emitting layer. Mass proportions of the carbon nanotubes in the first hole transport layer segment, the second hole transport layer segment, and the third hole transport layer segment are gradually increased.

For the quantum dot light-emitting layer with the higher valence band, the greater the mass proportion of the carbon nanotubes, the greater the hole mobility of the hole transport layer; and for the quantum dot light-emitting layer with the lower valence band, the less the mass proportion of the carbon nanotubes, the less the hole mobility of the hole transport layer, such that the overall hole mobility of the hole transport layer matches the valence band requirement of the quantum dot light-emitting layer.

In some embodiments, the quantum dot light-emitting layer includes red quantum dots, and the mass of the carbon nanotubes is 1% to 25% of the total mass of the hole transport material and the carbon nanotubes, which include, but is not limited to, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, and the like.

In some embodiments, the quantum dot light-emitting layer includes green quantum dots, and the mass of the carbon nanotubes is 5% to 45% of the total mass of the hole transport material and the carbon nanotubes, which include, but is not limited to, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, and the like.

In some embodiments, the quantum dot light-emitting layer includes blue quantum dots, and the mass of the carbon nanotubes is 25% to 65% of the total mass of the hole transport material and the carbon nanotubes, which include, but is not limited to, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, and the like.

The quantum dot electroluminescent device according to the embodiments of the present disclosure is partially encapsulated, fully encapsulated, or not encapsulated. Based on different emission types of quantum dot electroluminescent devices, the quantum dot electroluminescent device according to the embodiments of the present disclosure includes upright quantum dot electroluminescent devices and inverted quantum dot electroluminescent devices. In addition, the quantum dot electroluminescent device is top-emitted or bottom-emitted.

In some embodiments, the quantum dot electroluminescent device includes an upright bottom emitting device, an inverted bottom emitting device, an upright top emitting device, and an inverted top emitting device.

For the upright bottom emitting device, the inverted bottom emitting device, the upright top emitting device, and the inverted top emitting device, in addition to layers mentioned above, further layer structures are disposed according to actual needs, for example, a hole injection layer, an electron injection layer, an electron barrier layer, a hole barrier layer, an exciton barrier layer, an electrode modification layer, an isolation protective layer, and the like.

In some implementation, referring to FIG. 1, the upright bottom emitting device includes a transparent anode layer 101, a hole transport layer 200, a quantum dot light-emitting layer 300, an electron transport layer 400, and a reflective cathode layer 102 that are arranged in sequence from bottom to top.

In some implementation, the upright bottom emitting device includes a transparent anode layer, a hole injection layer, a hole transport layer, a quantum dot light-emitting layer, an electron transport layer, and a reflective cathode layer that are arranged in sequence from bottom to top (not shown in the drawings).

In some implementation, the upright bottom emitting device includes a transparent anode layer, a hole injection layer, a hole transport layer, a quantum dot light-emitting layer, an electron transport layer, an electron injection layer, and a reflective cathode layer that are arranged in sequence from bottom to top (not shown in the drawings).

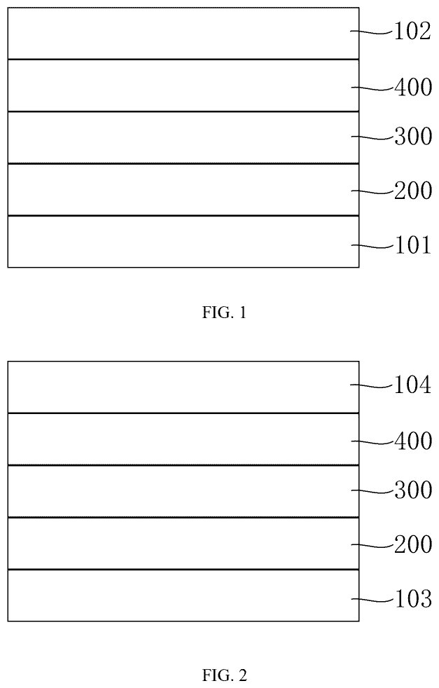

In some implementation, referring to FIG. 2, the inverted bottom emitting device includes a transparent cathode layer 103, a hole transport layer 200, a quantum dot light-emitting layer 300, an electron transport layer 400, and a reflective anode layer 104 that are arranged in sequence from bottom to top.

In some implementation, the inverted bottom emitting device includes a transparent cathode layer, a hole injection layer, a hole transport layer, a quantum dot light-emitting layer, an electron transport layer, and a reflective anode layer that are arranged in sequence from bottom to top (not shown in the drawings).

In some implementation, the inverted bottom emitting device includes a transparent cathode layer, a hole injection layer, a hole transport layer, a quantum dot light-emitting layer, an electron transport layer, an electron injection layer, and a reflective anode layer that are arranged in sequence from bottom to top (not shown in the drawings).

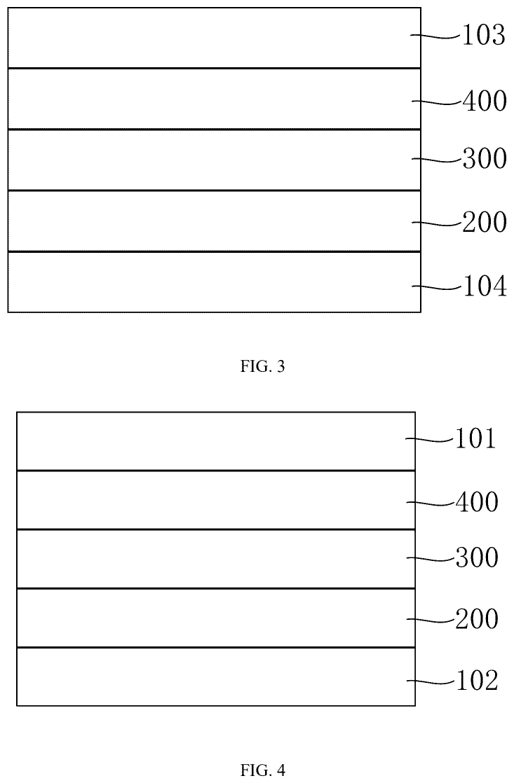

In some implementation, referring to FIG. 3, the upright top emitting device includes a substrate 100, a reflective anode layer 104, a hole transport layer 200, a quantum dot light-emitting layer 300, an electron transport layer 400, and a transparent cathode layer 103 that are arranged in sequence from bottom to top.

In some implementation, the upright top emitting device includes a reflective anode layer, a hole injection layer, a hole transport layer, a quantum dot light-emitting layer, an electron transport layer, and a transparent cathode layer that are arranged in sequence from bottom to top (not shown in the drawings).

In some implementation, the upright top emitting device includes a reflective anode layer, a hole injection layer, a hole transport layer, a quantum dot light-emitting layer, an electron transport layer, an electron injection layer, and a transparent cathode layer that are arranged in sequence from bottom to top (not shown in the drawings).

In some implementation, referring to FIG. 4, the inverted top emitting device includes a substrate 100, a reflective cathode layer 102, a hole transport layer 200, a quantum dot light-emitting layer 300, an electron transport layer 400, and a transparent anode layer 101 that are arranged in sequence from bottom to top.

In some implementation, the inverted top emitting device includes a reflective cathode layer, a hole injection layer, a hole transport layer, a quantum dot light-emitting layer, an electron transport layer, and a transparent anode layer that are arranged in sequence from bottom to top (not shown in the drawings).

In some implementation, the inverted top emitting device includes a reflective cathode layer, a hole injection layer, a hole transport layer, a quantum dot light-emitting layer, an electron transport layer, an electron injection layer, and a transparent anode layer that are arranged in sequence from bottom to top (not shown in the drawings).

Materials of other layers in the quantum dot electroluminescent device according to the embodiments of the present disclosure, for example, the quantum dot light-emitting layer, the electron transport layer, and the alternative hole injection layer and the alternative electron injection layer, and the like are common materials in the field, which are illustrated as follows.

The quantum dot light-emitting layer includes quantum dots, and some suitable quantum dots include, but are not limited to, CdS@ZnSZnS, CdSe@ZnS, InP@ZnS, PbS@ZnS, CsPbC13@ZnS, CsPbBr3@ZnS, CsPbI3@ZnS, CdS@ZnS, CdSe@ZnS, and the like.

The method for manufacturing the quantum dots is the conventional technical mean in the field. The process of manufacturing InP@ZnS are illustrated as follows.

In a glove box vacuum environment, 120.54 mg of indium bromide (InBr3) and 495.40 mg of zinc bromide (ZnBr2) were weighted using an electronic balance and added to a 50 ml three-necked flask, 5 ml of oleylamine (OLA) was added to the three-necked flask to evacuate for 30 min and heat to 100° C. until there is no water vapor.

Then, argon gas (Ar) was introduced into the three-necked flask to heat to 215° C., and a mixed solution of 0.45 ml of tris(dimethylamine)phosphine [(DMA) 3P] and 1.0 ml of oleylamine (OLA) was injected into the three-necked flask. The mixture was kept at the temperature for 20 minutes and was fully reacted at a suitable stirring speed, and then a 1.5 ml dodecyl mercaptan and 6 ml of stearic acid-octadecene (ODE) solution (15 g of zinc stearate is dissolved in 60 ml ODE) using a syringe.

Under the condition of maintaining a temperature of 200° C., samples were taken from the reactor at 10 min, 20 min, 30 min, and 40 min. After 40 min, heating was stopped, and the solution was cooled to 70° C.-80° C. Then, an amount of n-hexane was added, and centrifugation is performed at 10000 rpm to settle the zinc stearate.

An amount of n-hexane and anhydrous ethanol were added, and centrifugation is performed at 10000 rpm to settle the InP/ZnS nanocrystals to be dried using N2 to acquire the InP/ZnS nanocrystals, that is, InP@ZnS Quantum dots, which can be dissolved in an n-hexane solution. In the reaction process, the color of the reaction system changes from colorless and transparent to brown, and then gradually to yellow green.

The electron transport layer includes an electron transport material, and some suitable electron transport material include, but are not limited to, zinc oxide (ZnO), titanium dioxide (TiO2), tin oxide (SnO), magnesium zinc oxide (ZnMgO), aluminum zinc oxide (AlZnO), zinc tin oxide (ZnSnO), indium tin oxide (InSnO), aluminum 8-hydroxyquinoline (Alq3), lithium fluoride (LiF), and the like.

The hole injection layer includes a hole injection material, and some hole injection material include, but are not limited to, poly(3,4-ethylenedioxythiophene)/poly(styrene sulfonate) (PEDOT:PSS), copper(II) phthalocyanine (CuPc), 2,3,5,6-tetrafluoro-7,7′,8,8′-tetracyanoquino-dimethane (F4-TCNQ), dipyrazino[2,3-f: 2′,3′-h]quinoxaline-2,3,6,7,10,11-hexacarbonitrile (HATCN), or any combination thereof.

In some embodiments, various types of quantum dot electroluminescence devices described above include a substrate. The substrate is a rigid substrate or a flexible substrate. The rigid substrate includes, but is not limited to one or more of glass and metal foil. The flexible substrate includes, but is not limited to, one or more of polyethylene terephthalate (PET), polyethylene terephthalate (PEN), polyether ether ketone (PEEK), polystyrene (PS), polyether sulfone (PES), polycarbonate (PC), poly aryl ester (PAT), poly aryl ester (PAR), polyimide (PI), polyvinyl chloride (PV), polyethylene (PE), polyvinylpyrrolidone (PVP), and textile fiber.

In another aspect, some embodiments of the present disclosure further provide a method for manufacturing a quantum dot electroluminescent device. The quantum dot electroluminescent device is the quantum dot electroluminescent device described in above embodiments.

The method for manufacturing the quantum dot electroluminescent device includes forming an anode layer, a cathode layer, a quantum dot light-emitting layer, a hole transport layer, and an electron transport layer based on a structure of the quantum dot electroluminescent device.

The above layers are sequentially manufactured from bottom to top based on the structure of the quantum dot electroluminescent device.

The above layers of the quantum dot electroluminescent device are manufactured by chemical or physical method. The chemical method includes, but is not limited to, one or more of chemical vapor deposition, continuous ion layer adsorption and reaction method, anodic oxidation method, electrolytic deposition method, co-precipitation. The physical method includes, but is not limited to, physical coating method or solution method. The solution method includes, but is not limited to, spinning coating method, printing method, scraping coating method, dip and pull method, soaking method, spraying method, roll coating method, casting method, slit coating method, strip coating method, and the like. The physical coating method includes, but is not limited to, thermal evaporation coating method, electron beam evaporation coating method, magnetron sputtering method, multi-arc ion coating method, physical vapor deposition method, atomic layer deposition method, pulsed laser deposition method, and the like.

The manufacturing method is illustrated using an example where the quantum dot electroluminescent device is the upright bottom emitting device.

A transparent anode layer is cleaned. For example, the transparent anode layer is an ITO substrate or an LTC substrate. A hole injection layer is deposited on a surface of the transparent anode layer by spinning coating, a hole transport layer is deposited on a surface of the hole injection layer by spinning coating, a quantum dot light-emitting layer is deposited on a surface of the hole transport layer by spinning coating, an electron transport layer is deposited on a surface of the quantum dot light-emitting layer by spinning coating, and an electrode is evaporated on a surface of the electron transport layer and determined as a reflective cathode layer.

The method for manufacturing the hole transport layer includes providing a hole transport material and carbon nanotubes; acquiring a functional hole transport material by bonding the hole transport material to the carbon nanotubes; and acquiring the hole transport layer based on the functional hole transport material.

In some embodiments, the hole transport layer is formed by a solution method. For example, a dispersion of the functional hole transport material is acquired by uniformly dispersing the functional hole transport material in a solvent, a liquid film is formed by spin coating or scraping coating the dispersion of the functional hole transport material,, and the solvent in the liquid film is volatilized after drying and/or annealing treatment on the liquid film to form a dry hole transport layer.

Bonding modes of the hole transport material and the carbon nanotubes are different based on different types of hole transport materials, which are illustrated as follows.

In some examples (1), the hole transport material is an inorganic hole transport material, and the inorganic hole transport material is filled in lumens of the carbon nanotubes.

In conjunction with FIG. 5, acquiring the functional hole transport material by bonding the hole transport material to the carbon nanotubes includes the following processes.

In S11, mouths of the carbon nanotubes are opened.

In S12, a first intermediate of the functional hole transport material is acquired by causing a metal salt solution corresponding to the inorganic hole transport material to enter the lumens of the carbon nanotubes. A surface tension of the metal salt solution is less than a predetermined threshold.

In S13, the functional hole transport material is acquired by drying and annealing the first intermediate of the functional hole transport material.

For S11, the carbon nanotube is generally of a hollow tubular structure, and two ends of the carbon nanotube are generally closed along the axial direction. The cap-shaped portion in the carbon nanotube port has stronger mobility due to the pentagonal structure and the large curved rate, and thus the mouth of the carbon nanotube is openable under some operating conditions.

In some embodiments, under the action of an alternative catalyst, the mouth of the carbon nanotube is opened by acid (acid oxidizes the mouth of the carbon nanotube), which has advantages of low operating temperature and easy operation. The catalyst includes, but is not limited to, lead (Pb), and the acid includes, but is not limited to, nitric acid, sulfuric acid, and other strong acid solutions.

In some embodiments, the carbon nanotube is heated to a target temperature in the air to oxidize the port to open the mouth. For example, the target temperature ranges from 700° C.- 750° C.

For S12, based on the metal elements in the inorganic hole transport material, a metal salt solution corresponding to the metal elements is prepared (referred to as the metal salt solution corresponding to the inorganic hole transport material). Based on the capillary action, the metal salt solution corresponding to the inorganic hole transport material enters the lumens of the carbon nanotubes. As the surface tension of the metal salt solution is less than the predetermined threshold, the metal salt solution with low surface tension is prone to entering the lumens of the carbon nanotubes based on the capillary action. In some embodiments, the surface tension of the metal salt solution ranges from 100 mN/m to 200 mN/m.

The metal salt solution corresponding to the inorganic hole transport material herein includes the metal salt and the acid solution. For example, the acid solution is a strong acid solution such as nitric acid solution and sulfuric acid solution, and the strong acid is capable of oxidizing the mouth of the carbon nanotube to promote opening of the mouth of the carbon nanotube.

In some embodiments, metal salts include metal nitrates, metal sulfates, and the like, which facilitate uniform dispersion in the acid.

Illustratively, some suitable metal salts are nickel nitrate, molybdenum nitrate, vanadium nitrate, tungsten nitrate, chromium nitrate, nickel sulfate, molybdenum sulfate, vanadium sulfate, tungsten sulfate, chromium sulfate, and the like.

In general, for the above strong acid solution of the nickel salt, the molybdenum salt, the vanadium salt, the tungsten salt, the chromium salt, and the like, the surface tension is generally less than 200 mN/m to facilitate entering the lumen of the carbon nanotube.

An amount of metal salt corresponding to the carbon nanotubes and inorganic hole transport materials in the feedstock system is determined based on the amount of carbon nanotubes, and then the amount of strong acid solution, such as nitric or sulfuric acid, is further determined.

Upon determination of the feedstock system, the feedstock system is refluxed at a predetermined temperature for a predetermined duration to ensure that the metal salt solution is fully filled into the lumen of the carbon nanotube. The amount of metal salt solution filled into the carbon nanotube is proportional to both the reflux temperature and reflux duration.

For example, the reflux temperature ranges from 100° C. to 180° C., which includes, but is not limited to, 100° C., 110° C., 120° C., 130° C., 140° C., 150° C., 160° C., 170° C., 180° C., and the like; and the reflux duration ranges from 2 hours to 10 hours, which includes, but is not limited to, 2 hours, 3 hours, 4 hours, 5 hours, 6 hours, 7 hours, 8 hours, 9 hours, 10 hours, and the like.

After the reflux treatment, the acquired suspension is settled, and the sediment is collected and dried. For example, the drying treatment includes heating at 90° C. to 120° C. for 6 hours to 24 hours to remove the acid and water and acquire the dried product. The dried product includes the carbon nanotubes and the metal salt in the lumens of the carbon nanotubes.

Annealing treatment is performed on the dried product, such that the metal salt inside the carbon nanotubes is converted into metal oxide. The metal oxide is the inorganic hole transport material in the form of oxides. For example, the metal oxide includes, but is not limited to, NiOx, MoOx, VOx, WOx, CrOx, CuO, and the like.

Depending on the type of metal, the annealing temperature and the annealing duration are determined, as long as the metal salt is fully converted into the metal oxide.

It can be seen that in the above manufacturing method, the inorganic hole transport material in the form of oxide is formed in the carbon nanotubes, such that the hole mobility of the hole transport layer is effectively improved, and the carrier balance of quantum dot electroluminescent device is promoted.

Prior to manufacturing the quantum dot electroluminescent device, the manufactured functional hole transport material was dispersed in the solvent, such as chloroform, chlorobenzene, and the like. Each 1 mg of functional hole transport material corresponds to 8 mL to 10 ml of solvent, and then ultrasonic stirring was performed for 5 hours to 15 hours, such as 12 hours, and the like, such that the functional hole transport material was fully dispersed in the solvent. The dispersion of the functional hole transport material was acquired for backup. In manufacturing the hole transport layer, the dispersion of the functional hole transport material is directly used, or is ultrasonic treated for 2 to 5 minutes to decompose clusters and aggregates and then used.

Using an example where the functional hole transport material includes the NiOx and the carbon nanotubes, the method for manufacturing the functional hole transport material is described in detail.

An amount (for example, 0.4 g) of carbon nanotube material was added to an amount of nickel nitrate solution. The solute of the nickel nitrate solution is nickel nitrate hydrate (Ni(NO3)2·6H2O), and the solvent is nitric acid. For example, the amount of nickel nitrate hydrate is 1 g, and the amount of nitric acid is 20 g.

The feedstock system was refluxed in an oil bath at 140° C. for 4 hours to cause the hydrated nickel nitrate to fully enter the lumens of the carbon nanotubes, such that a suspension was formed.

The suspension was settled, the black precipitate was collected and heated at 100° C. for 12 h to dry, and the powdered product was acquired.

The powdered product was heated to 450° C. and annealed at the temperature for 5 h. In this case, the hydrated nickel nitrate was converted into nickel oxide in the lumens of the carbon nanotubes, and the functional hole transport materials including NiOx and carbon nanotubes are prepared.

In some examples (2), the hole transport material is an inorganic hole transport material, and the inorganic hole transport material is filled in lumens of the carbon nanotubes.

Acquiring the functional hole transport material by bonding the hole transport material to the carbon nanotubes includes the following processes.

In S21, mouths of the carbon nanotubes are opened.

In S22, a second intermediate of the functional hole transport material is acquired by causing a dispersion of the inorganic hole transport material to enter the lumens of the carbon nanotubes.

In S23, the functional hole transport material is acquired by post-processing the second intermediate of the functional hole transport material.

For the operations of S21, reference may be made to S11, which are not repeated herein.

For S22, the dispersion of the inorganic hole transport material includes an inorganic hole transport material and a solvent. The solvent is a good solvent of the inorganic hole transport material, such that the inorganic hole transport material is uniformly dispersed.

Illustratively, the inorganic hole transport material is CuO, MoS2, MoSe2, WS2, WSe2, CuS, or any combination thereof. For example, for the dispersion of CuO, the solvent is a strong acid (sulfuric acid, hydrochloric acid, nitric acid), a mixed solution of ammonium chloride and ammonia water, and the like. For the dispersion of MoS2 and the dispersion of MoSe2, the solvent is concentrated sulfuric acid. For the dispersion of WS2 and the dispersion of WSe2, the solvent is hot water. For the dispersion of CuS, the solvent is concentrated nitric acid.

The dispersion is formed by dispersing the inorganic hole transport material in the solvent, such that the dispersion of the inorganic hole transport material enters the lumens of the carbon nanotubes. That is, the inorganic hole transport material enters the lumens of the carbon nanotubes.

For S23, post-processing is performed on the second intermediate of the functional hole transport material. For example, the post-processing is drying processing or other processes, as long as the solvent in the dispersion is removed and only the inorganic hole material is remained in the carbon nanotubes, such that the functional hole transport material is acquired.

The inorganic hole transport material in the functional hole transport material manufactured by the above method may be in non-oxide form, such as metal sulfide compounds, including, but not limited to, MoS2, MoSe2, WS2, WSe2, CuS, or any combination thereof.

Prior to manufacturing the quantum dot electroluminescent device, the functional hole transport material was dispersed in the solvent, such as chloroform, chlorobenzene, and the like. Each 1 mg of functional hole transport material corresponds to 8 mL to 10 mL of solvent, and then ultrasonic stirring was performed for 5 hours to 15 hours, such as 12 hours, and the like, such that the functional hole transport material was fully dispersed in the solvent. The dispersion of the functional hole transport material was acquired for backup. In manufacturing the hole transport layer, the dispersion of the functional hole transport material is directly used, or is ultrasonic treated for 2 to 5 minutes to decompose clusters and aggregates and then used.

In some examples (3), the hole transport material is an organic hole transport material, and the organic hole transport material is bonded to surfaces of the carbon nanotubes.

Acquiring the functional hole transport material by bonding the hole transport material to the carbon nanotubes includes the following processes.

In S31, carbon nanotubes are uniformly dispersed in a dispersion of the organic hole transport material, and the organic hole transport material is bonded to surfaces of the carbon nanotubes through a noncovalent bonding force to acquire a product system.

In S32, the product system is purified to remove the carbon nanotubes and the organic hole transport material that are not bonded, such that the functional hole transport material is acquired.

For the organic hole transport material, the carbon nanotubes are uniformly dispersed in the dispersion of the organic hole transport material, such that the organic hole transport material is bonded to outer walls of the carbon nanotubes through the noncovalent bonding force. Furthermore, the product system is purified to remove the carbon nanotubes and the organic hole transport material that are not bonded, such that the carbon nanotubes and the organic hole transport material are bonded in the acquired product.

For S31, the dispersion of the organic hole transport material contains the organic hole transport material and the solvent, and is acquired by dissolving the organic hole transport material in the solvent and performing ultrasonic treatment. The ultrasonic treatment duration is at least 30 minutes, for example, 30 minutes to 120 minutes. Using an example where the organic hole transport material is P3HT, P3HT is dissolved in chlorobenzene and ultrasonic treated in the ultrasonic equipment for 60 minutes, such that the uniform dispersion of the organic hole transport material is acquired.

In order to ensure that more organic hole transport material is bonded to the surfaces of the carbon nanotubes through non-covalent bonding face, the mixed solution of the carbon nanotubes and the dispersion of the organic hole transport material was ultrasonic treated for 5 to 20 minutes. For example, the duration includes, but is not limited to, 5 minutes, 7 minutes, 10 minutes, 11 minutes, 12 minutes, 13 minutes, 14 minutes, 15 minutes, 16 minutes, 17 minutes, 18 minutes, 19 minutes, 20 minutes, and the like. The organic hole transport material was stably bonded to the surfaces of carbon nanotubes by the ultrasonic treatment.

For S32, the product system is purified to remove the carbon nanotubes and the organic hole transport material that are not bonded, such that the functional hole transport material is acquired. The purification treatment includes centrifugation treatment and solvent extraction treatment in sequence.

The not bonded carbon nanotubes are removed by the centrifugation treatment, and the not bonded organic hole transport material is removed by the solvent extraction treatment, such that the high purity functional hole transport material, that is, the carbon nanotubes and the organic hole transport material that are bonded, is remained in the product system.

The centrifugation treatment and the solvent extraction treatment may be performed several times, such as twice, three times, four times, or more, such that the proportion of the functional hole transport material in the final product is greater than 98%, with the expectation of 100%.

In the case that the feedstock system includes the organic hole transport material and the carbon nanotubes, processes of an illustrative method for manufacturing the functional hole transport material are as follows.

In a first process, the organic hole transport material is dissolved in the solvent. For example, each 1 mg of organic hole transport material corresponds to 1.5 mL to 3 mL of solvent, and then ultrasonic treatment is performed for 30 minutes to 120 minutes, such that the dispersion of the organic hole transport material is acquired.

In a second process, an amount of carbon nanotubes is added to the dispersion of the organic hole transport material, and then ultrasonic treatment is performed for 5 minutes to 20 minutes to acquire a first product system.

In a third process, the first product system is centrifuged for 5 minutes to 15 minutes, a centrifugal force in centrifugation ranges from 8000 g to 12000 g to remove the carbon nanotubes and other carbon particles that are not bonded, and the supernatant is recovered.

In a fourth process, the supernatant is subjected to solvent extraction treatment, which includes: adding toluene to the supernatant, heating the mixture of the toluene and the supernatant at a temperature of 30° C. to 80° C. for 15 to 120 minutes to induce aggregation of the functional hole transport material, and removing the aggregated products by centrifugation. The centrifugal force in centrifugation ranges from 12000 g to 18000 g, and the duration ranges from 3 minutes to 10 minutes. Then the supernatant containing not bonded organic hole transport material is discarded, and the aggregated product is recovered.

In a fifth process, a second product system is acquired by redispersing the aggregated product into the toluene, and then ultrasonic treatment is performed on the second product system for 10 minutes to 25 minutes to redissolve the not bonded organic hole transport material, such that a third product system is acquired. The third product system is heated at a temperature of 30° C. to 80° C. for 15 to 120 minutes to induce aggregation of the functional hole transport material, and the aggregated products are removed by centrifugation. The centrifugal force in centrifugation ranges from 12000 g to 18000 g, and the duration ranges from 3 minutes to 10 minutes. Then the supernatant containing not bonded organic hole transport material is discarded, and the aggregated product is recovered.

The fifth process can be performed several times, for example, twice, three times, four times, five times, and the like, until the not bonded organic hole transport material is completely removed, and the final supernatant is completely transparent. Then, the final precipitate is acquired, that is, the functional hole transport material is acquired.

Prior to manufacturing the quantum dot electroluminescent device, the functional hole transport material was dispersed in the solvent, such as chloroform, chlorobenzene, and the like. Each 1 mg of functional hole transport material corresponds to 8 mL to 10 mL of solvent, and then ultrasonic stirring was performed for 5 hours to 15 hours, such as 12 hours, and the like, such that the functional hole transport material was fully dispersed in the solvent. The dispersion of the functional hole transport material was acquired for backup. In manufacturing the hole transport layer, the dispersion of the functional hole transport material is directly used, or is ultrasonic treated for 2 to 5 minutes to decompose clusters and aggregates and then used.

Some embodiments of the present disclosure further provide the implementations of the functional hole transport material. The functional hole transport material includes the carbon nanotubes and the organic hole transport material P3HT bonded to the carbon nanotubes. The method for manufacturing the functional hole transport material is as follows.

In a first process, 3.0 mg P 3HT is dissolved in 5 mL chlorobenzene, and then ultrasonic treatment is performed for 60 minutes, such that the dispersion of the organic hole transport material is acquired.

In a second process, 2.0 mg carbon nanotubes are added to the dispersion of the organic hole transport material, and then ultrasonic treatment is performed for 10 minutes to acquire a first product system.

In a third process, the first product system is centrifuged for 8 minutes, a centrifugal force in centrifugation is 10000 g to remove the carbon nanotubes and other carbon particles that are not bonded, and the supernatant is recovered.

In a fourth process, the supernatant is subjected to solvent extraction treatment, which includes: adding 15 mL toluene to the supernatant, heating the mixture of the toluene and the supernatant at 50 ° C. for 60 minutes to induce aggregation of the functional hole transport material, and removing the aggregated products by centrifugation. The centrifugal force in centrifugation is 16000 g, and the duration is 4 minutes. Then the supernatant containing not bonded organic hole transport material is discarded, and the aggregated product is recovered.

In a fifth process, a second product system is acquired by redispersing the aggregated product into 5 mL toluene, and then ultrasonic treatment is performed on the second product system for 15 minutes to redissolve the not bonded organic hole transport material, such that a third product system is acquired. The third product system is heated at 50° C. for 15 minutes to induce aggregation of the functional hole transport material, and the aggregated products are removed by centrifugation. The centrifugal force in centrifugation is 16000 g, and the duration is 4 minutes. Then the supernatant containing not bonded organic hole transport material is discarded, and the aggregated product is recovered. The fifth process is repeated three times until the final supernatant is completely transparent. Then, the final functional hole transport material is acquired.

In another aspect, a display device is provided in some embodiments of the present disclosure. the display device includes any of above quantum dot electroluminescent device.

The display device according to the embodiments of the present disclosure have all advantages of the quantum dot electroluminescent device according to the embodiments of the present disclosure.

Illustratively, the display device includes, but is not limited to, a television, a mobile phone, a tablet computer, a monitor, a vehicle display, and the like.

In the embodiments of the present disclosure, the terms “first” and “second” are only intended to describe, and are not intended to indicate or imply relative importance. The term “a plurality of” herein means two or more, unless otherwise defined clearly.

The phrase in the embodiments of the present disclosure “and/or” means an association relation between associated objects and indicates three relations. For example, A and/or B means (A), (B), or (A and B).

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

1. A quantum dot electroluminescent device, comprising: an anode layer, a functional layer, and a cathode layer that are stacked; wherein
the functional layer comprises a quantum dot light-emitting layer, and a hole transport layer and an electron transport layer that are disposed on two sides of the quantum dot light-emitting layer, wherein the hole transport layer comprises a hole transport material and carbon nanotubes, the hole transport material being bonded to the carbon nanotubes.

2. The quantum dot electroluminescent device according to claim 1, wherein the hole transport material is an inorganic hole transport material, wherein the inorganic hole transport material is filled in lumens of the carbon nanotubes.

3. The quantum dot electroluminescent device according to claim 2, wherein the carbon nanotubes are in contact with the anode layer.

4. The quantum dot electroluminescent device according to claim 2, wherein the inorganic hole transport material is selected from NiOx, MoOx, VOx, WOx, CrOx, CuO, MoS2, MoSe2, WS2, WSe2, CuS, or any combination thereof.

5. The quantum dot electroluminescent device according to claim 1, wherein the hole transport material is an organic hole transport material, wherein at least part of the organic hole transport material is bonded to the carbon nanotubes through a noncovalent bonding force and is on outer surfaces of the carbon nanotubes.

6. The quantum dot electroluminescent device according to claim 5, wherein the carbon nanotubes and the organic hole transport material are both in contact with the anode layer.

7. The quantum dot electroluminescent device according to claim 5, wherein the organic hole transport material is selected from poly (9,9-dioctylfluorene-co-N-(4-butylphenyl) diphenylamine (TFB), polyvinyl carbazole (PVK), poly (N,N′-bis(4-butylphenyl)-N,N′-bis(phenyl)benzidine) (poly TPD), poly(9,9-dioctylfluorene-co-bis-N, N-phenyl-1,4-phenylenediamine) (PFB), 4,4′,4″-tri(carbazole-9-yl) triphenylamine (TCTA), 4,4′-di(9-carbazole)biphenyl (CBP), N,N′-diphenyl-N,N′-di(3-methylphenyl)-1,1′-biphenyl-4,4′-diamine (TPD), N,N′-diphenyl-N,N′-(1-naphthyl)-1,1′-biphenyl-4,4′-diamine (NPB), poly-3-hexylthiophene (P3HT), or any combination thereof.

8. The quantum dot electroluminescent device according to claim 1, wherein a mass of the carbon nanotubes is 1% to 65% of a total mass of the hole transport material and the carbon nanotubes.

9. The quantum dot electroluminescent device according to claim 8, comprising: a red quantum dot light-emitting layer, a green quantum dot light-emitting layer, and a blue quantum dot light-emitting layer; wherein
the hole transport layer comprises a first hole transport layer segment, a second hole transport layer segment, and a third hole transport layer segment, wherein the first hole transport layer segment corresponds to the red quantum dot light-emitting layer, the second hole transport layer segment corresponds to the green quantum dot light-emitting layer, and the third hole transport layer segment corresponds to the blue quantum dot light-emitting layer, wherein mass proportions of the carbon nanotubes in the first hole transport layer segment, the second hole transport layer segment, and the third hole transport layer segment are gradually increased.

10. The quantum dot electroluminescent device according to claim 8, wherein
the quantum dot light-emitting layer comprises red quantum dots, and the mass of the carbon nanotubes is 1% to 25% of the total mass of the hole transport material and the carbon nanotubes; or
the quantum dot light-emitting layer comprises green quantum dots, and the mass of the carbon nanotubes is 5% to 45% of the total mass of the hole transport material and the carbon nanotubes; or
the quantum dot light-emitting layer comprises blue quantum dots, and the mass of the carbon nanotubes is 25% to 65% of the total mass of the hole transport material and the carbon nanotubes.

11. The quantum dot electroluminescent device according to claim 1, comprising: an upright bottom emitting device, an inverted bottom emitting device, an upright top emitting device, and an inverted top emitting device.

12. A method for manufacturing a quantum dot electroluminescent device, wherein the quantum dot electroluminescent device is defined in claim 1, and the manufacturing method comprises: forming an anode layer, a cathode layer, a quantum dot light-emitting layer, a hole transport layer, and an electron transport layer based on a structure of the quantum dot electroluminescent device; wherein forming the hole transport layer comprises:
providing a hole transport material and carbon nanotubes;
acquiring a functional hole transport material by bonding the hole transport material to the carbon nanotubes; and
acquiring the hole transport layer based on the functional hole transport material.

13. The method for manufacturing the quantum dot electroluminescent device according to claim 12, wherein the hole transport material is an inorganic hole transport material, the inorganic hole transport material being filled in lumens of the carbon nanotubes; and acquiring the functional hole transport material by bonding the hole transport material to the carbon nanotubes comprises:
opening mouths of the carbon nanotubes;
acquiring a first intermediate of the functional hole transport material by causing a metal salt solution corresponding to the inorganic hole transport material to enter the lumens of the carbon nanotubes, wherein a surface tension of the metal salt solution is less than a predetermined threshold; and
acquiring the functional hole transport material by drying and annealing the first intermediate of the functional hole transport material.

14. The method for manufacturing the quantum dot electroluminescent device according to claim 13, wherein the surface tension of the metal salt solution ranges from 100 mN/m to 200 mN/m.

15. The method for manufacturing the quantum dot electroluminescent device according to claim 12, wherein the hole transport material is an inorganic hole transport material, the inorganic hole transport material being in lumens of the carbon nanotubes; and acquiring the functional hole transport material by bonding the hole transport material to the carbon nanotubes comprises:
opening mouths of the carbon nanotubes;
acquiring a second intermediate of the functional hole transport material by causing a dispersion of the inorganic hole transport material to enter the lumens of the carbon nanotubes; and
acquiring the functional hole transport material by post-processing the second intermediate of the functional hole transport material.

16. The method for manufacturing the quantum dot electroluminescent device according to claim 12, wherein the hole transport material is an organic hole transport material, the organic hole transport material being bonded to surfaces of the carbon nanotubes through a noncovalent bonding force; and acquiring the functional hole transport material by bonding the hole transport material to the carbon nanotubes comprises:
acquiring a dispersion of the organic hole transport material by uniformly dispersing the organic hole transport material in a solvent;
uniformly dispersing the carbon nanotubes in the dispersion of the organic hole transport material; and
acquiring the functional hole transport material by purifying the dispersion of the organic hole transport material mixed with the carbon nanotubes.

17. The method for manufacturing the quantum dot electroluminescent device according to claim 16, wherein purifying the dispersion of the organic hole transport material mixed with the carbon nanotubes comprises a centrifugation process and a solvent extraction process in sequence.

18. A display device, comprising: a quantum dot electroluminescent device, wherein the quantum dot electroluminescent device comprises an anode layer, a functional layer, and a cathode layer that are stacked; wherein
the functional layer comprises a quantum dot light-emitting layer, and a hole transport layer and an electron transport layer that are disposed on two sides of the quantum dot light-emitting layer, wherein the hole transport layer comprises a hole transport material and carbon nanotubes, the hole transport material being bonded to the carbon nanotubes.

19. The display device according to claim 18, wherein the hole transport material is an inorganic hole transport material, wherein the inorganic hole transport material is filled in lumens of the carbon nanotubes.

20. The display device according to claim 19, wherein the carbon nanotubes are in contact with the anode layer.
